(19) United States
(12) Patent Application Publication
(10) Pub. No.: US 2025/0239517 A1
(43) Pub. Date: Jul. 24, 2025

(54) SEMICONDUCTOR PACKAGE AND METHOD FOR FORMING THE SAME

(71) Applicant: MEDIATEK INC., Hsinchu City (TW)

(72) Inventors: Yi-Chieh LIN, Hsinchu City (TW); Sang-Mao CHIU, Hsinchu City (TW); Kai-Cheng WANG, Hsinchu City (TW); Ya-Jui HSIEH, Hsinchu City (TW)

(21) Appl. No.: 19/021,721

(22) Filed: Jan. 15, 2025

Related U.S. Application Data
(60) Provisional application No. 63/622,597, filed on Jan. 19, 2024.

(51) Int. Cl. H01L 23/498; H01L 21/48; H01L 25/18; H10D 1/20

(52) U.S. Cl. CPC H01L 23/49838; H01L 21/4857; H01L 21/486; H01L 23/49822; H01L 25/18; H10D 1/20

(57) ABSTRACT

A semiconductor package and a method for forming the same are provided. The semiconductor package includes a substrate. The substrate includes a core and a redistribution layer structure and an inductor. The redistribution layer structure is disposed on the core. The inductor is embedded in redistribution layer structure. The inductor includes a first conductive layer, a conductive post and a second conductive layer. The first conductive layer is disposed on the core. The conductive post is disposed on the first conductive layer. The second conductive layer is disposed on the conductive post. The conductive post and a via of the redistribution layer structure are located at the same level. In a plan view, a first area of the conductive post is greater than a second area of the via.

### CROSS REFERENCE TO RELATED APPLICATIONS

This application claims the benefit of U.S. Provisional Application No. 63/622,597, filed on Jan. 19, 2024, the entirety of which is incorporated by reference herein.

### BACKGROUND OF THE DISCLOSURE

### Field of the Disclosure

The present disclosure relates to a semiconductor package and a method for forming the same and, in particular, it relates to a package substrate having embedded inductors and a method for forming the same.

### Description of the Related Art

Inductors are essential in fully integrated voltage regulators (FIVRs) and other electronic products for energy storage, noise filtering, and current smoothing. These inductors also have functions that maintain high efficiency and stable output voltage.

In a conventional semiconductor package, one criterion of inductors is low resistance, so that a high quality factor (Q factor) can be achieved. The Q factor of an inductor is the ratio of its inductive reactance to its resistance at a given frequency, and is a measure of its efficiency. The higher the Q factor of the inductor, the closer it approaches the behavior of an ideal, lossless, inductor.

Thus, a novel semiconductor package having an inductor with an increased Q factor is desirable.

### BRIEF SUMMARY OF THE DISCLOSURE

An embodiment of the present disclosure provides a semiconductor package. The semiconductor package includes a substrate. The substrate includes a core, a redistribution layer structure and an inductor. The redistribution layer structure is disposed on the core. The inductor is embedded in redistribution layer structure. The inductor includes a first conductive layer, a conductive post and a second conductive layer. The first conductive layer is disposed on the core. The conductive post is disposed on the first conductive layer. The second conductive layer is disposed on the conductive post. The conductive post and a via of the redistribution layer structure are located at the same level and have different areas. In a plan view, a first area of the conductive post is greater than a second area of the via.

An embodiment of the present disclosure provides a method for forming a semiconductor package. The method for forming a semiconductor package includes forming a first conductive layer and a first conductive trace on a core. The method further includes forming a first insulating film on the first conductive layer and the first conductive trace. The method further includes forming a first opening in the first insulating film by etching process to form a first patterned insulating film. The method further includes forming a conductive post on the first conductive layer and in the first opening. The method further includes forming an insulating layer on the conductive post and the first conductive trace. The method further includes forming a second opening in the insulating layer by drilling process to expose the first conductive trace. The method further includes forming a second conductive layer and a via in the second opening. The second conductive layer is connected to the conductive post, and the via is connected to the first conductive trace.

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view of a substrate of a semiconductor package in accordance with some embodiments of the disclosure;

FIG. 2A is a schematic plan view of a portion of the substrate of the semiconductor package of FIG. 1;

FIG. 2B is a schematic plan view of a portion of the substrate of the semiconductor package of FIG. 1;

FIGS. 3A and 3B are perspective views of the portion of the substrate of FIGS. 2A and 2B;

FIGS. 4A, 4B, 4C, 4D, 4E, 4F, 4G and 4H are enlarge views of FIGS. 2A and 2B, showing the arrangements of a conductive post and a conductive layer of the inductor;

FIGS. 5, 6, 7 and 8 are schematic cross-sectional views of a semiconductor package in accordance with some embodiments of the disclosure, showing the connections between the inductor of FIG. 1 and other inductors of the semiconductor package; and

FIGS. 9, 10, 11, 12, 13 and 14 are schematic cross-sectional views at intermediate stages of forming the substrate of the semiconductor package of FIG. 1 in accordance with some embodiments of the disclosure.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

In the conventional semiconductor package, the power inductor is usually manufactured in a structure in which a plurality of ferrites in the coil center and the coil patterns overlap each other in a vertical direction in which the sheets are laminated. However, the magnetic material has a relatively low saturation magnetization value when compared to conventional air-core inductor technology, and thus, the magnetic material may not realize high current properties that are required for the artificial intelligence (AI) servers. Another conventional power air-core inductor is manufactured in a structure in which the coil patterns overlap each other are formed by alternately arranged parallel wirings and vias. However, the Q factor of the air-core inductor is need to be improved. Thus, a novel inductor for a semiconductor package is desirable.

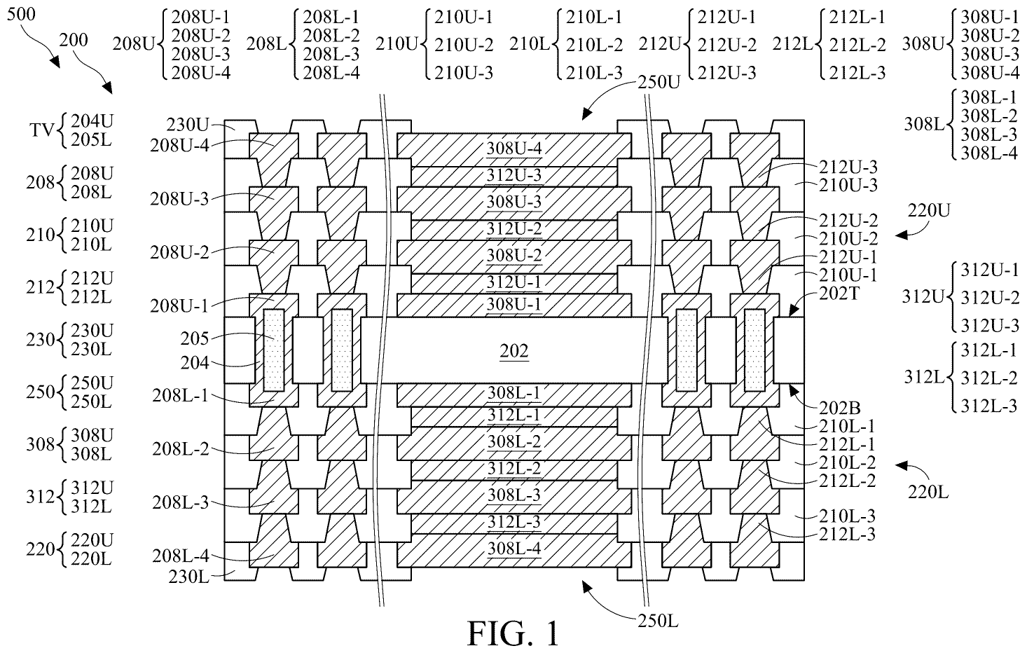

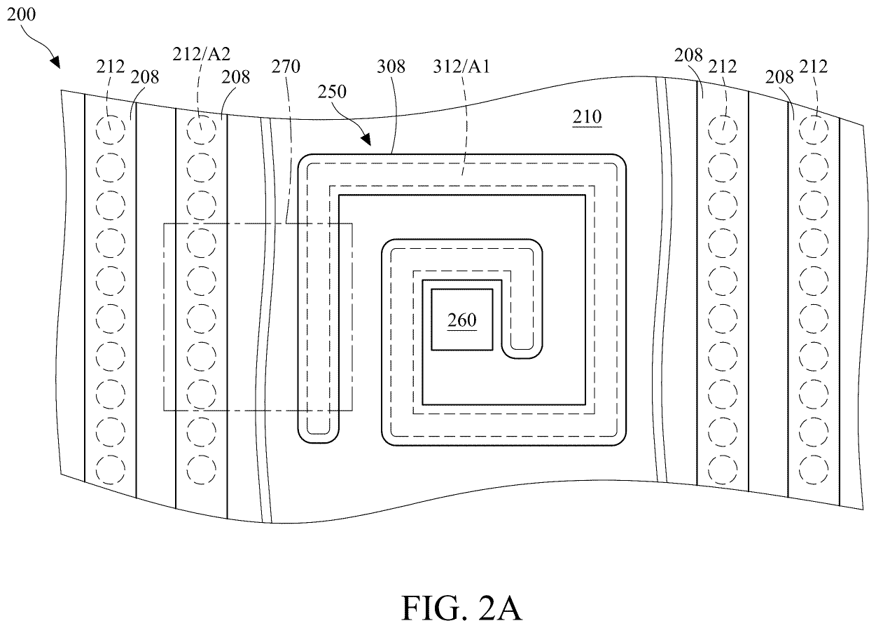

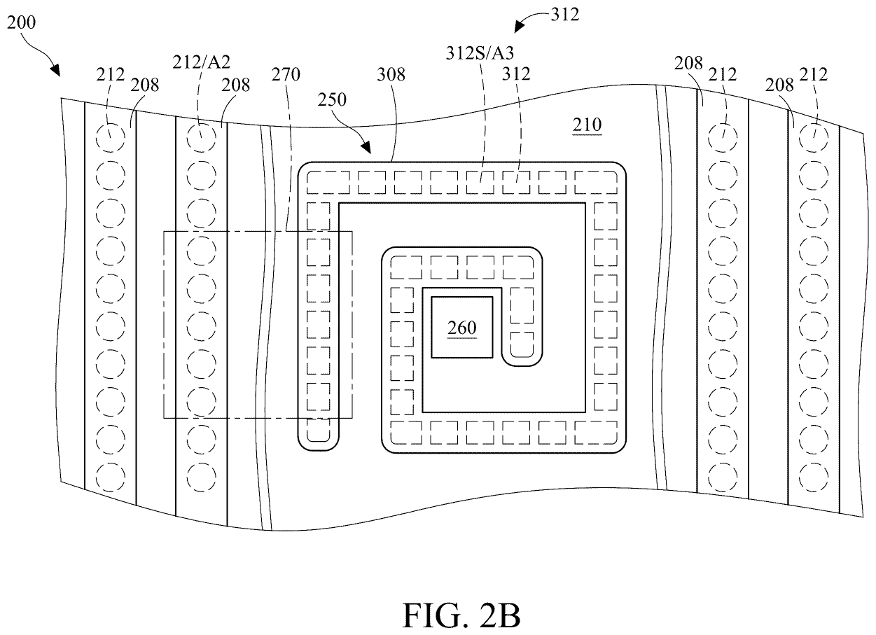

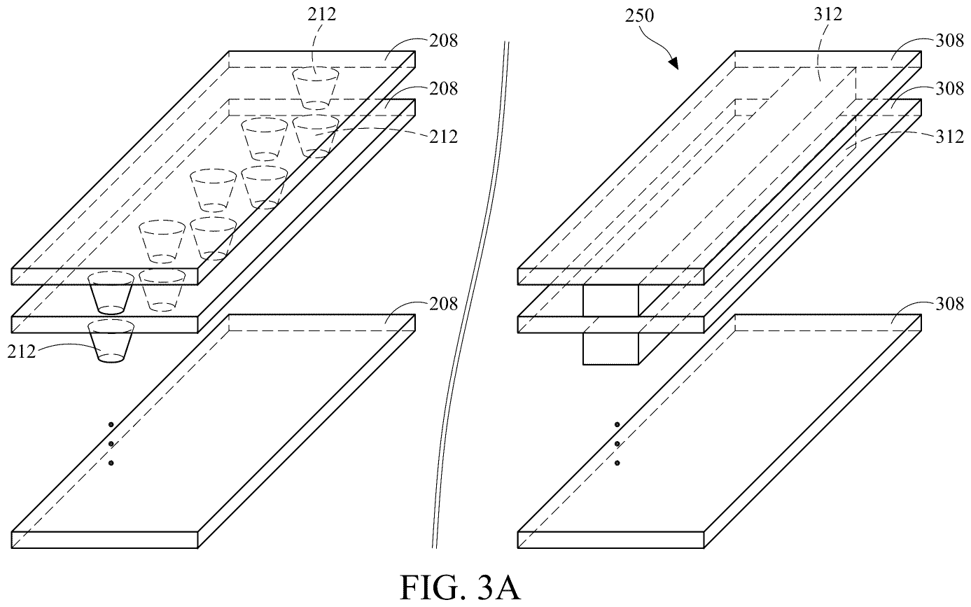

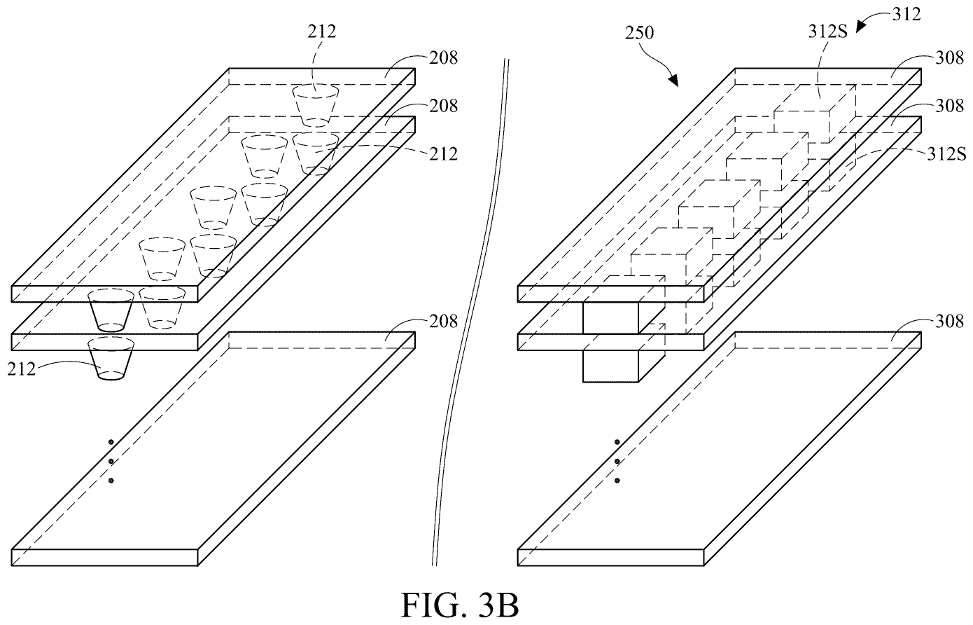

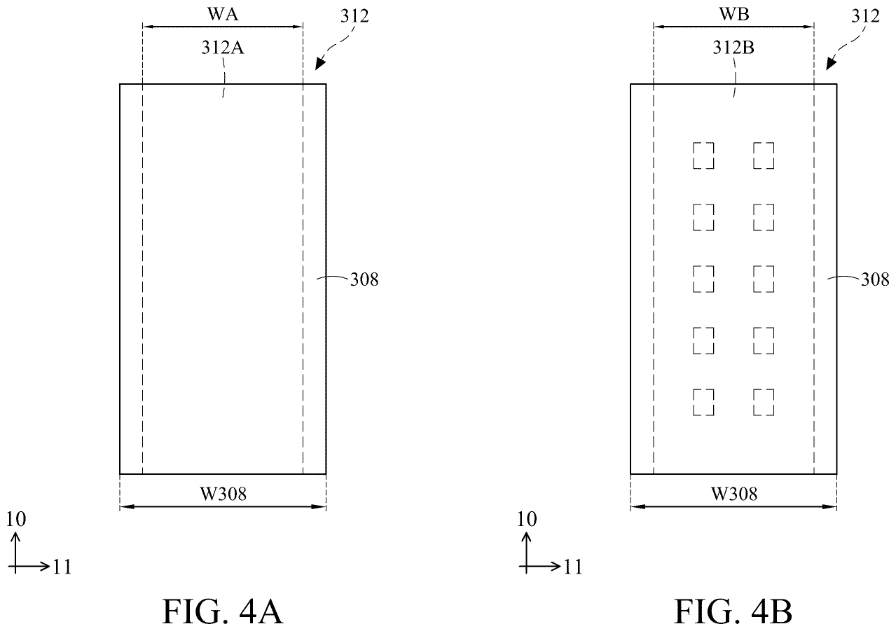

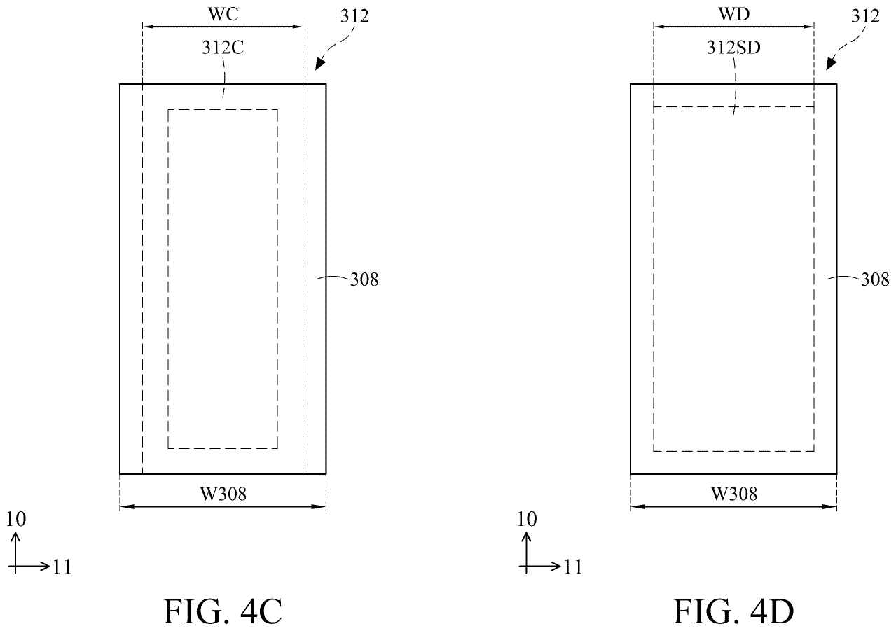

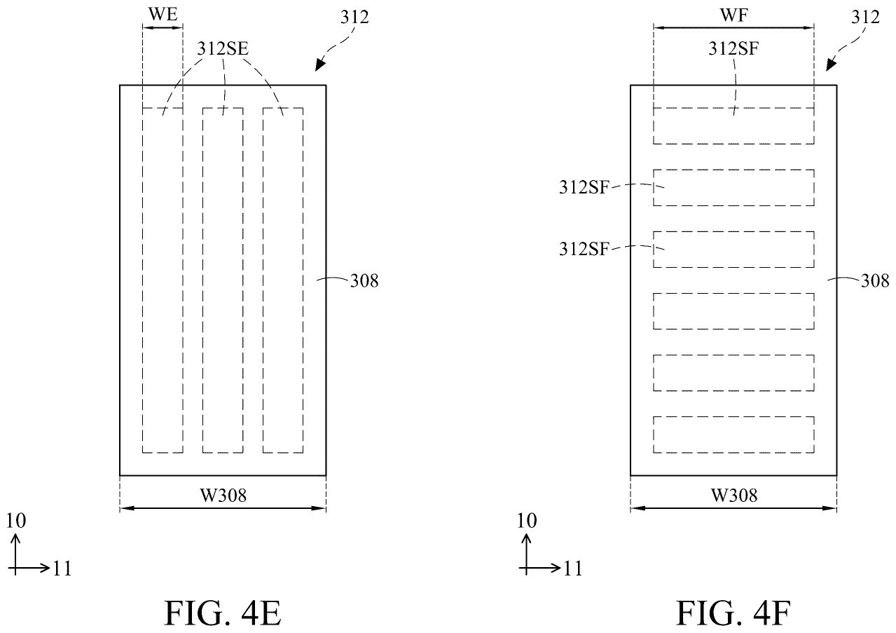

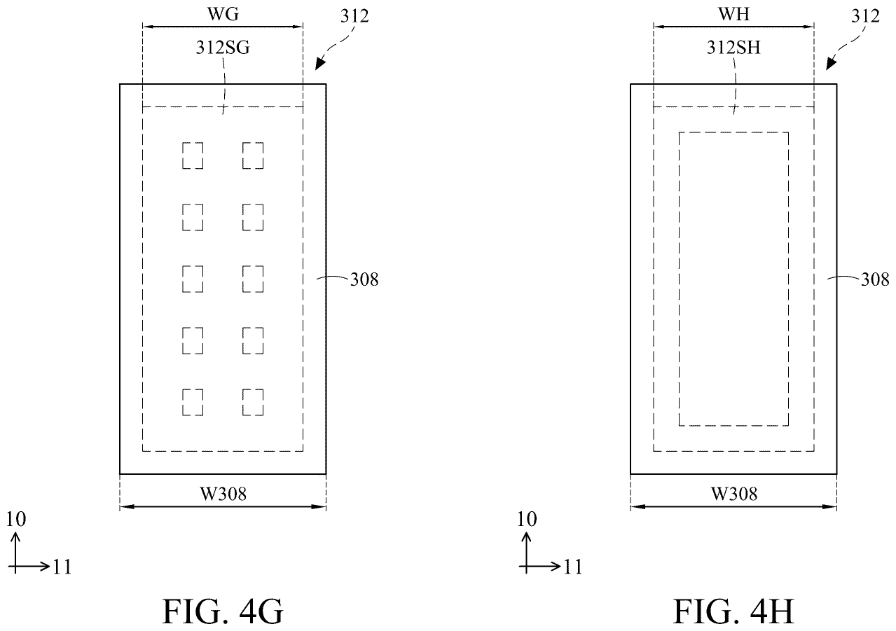

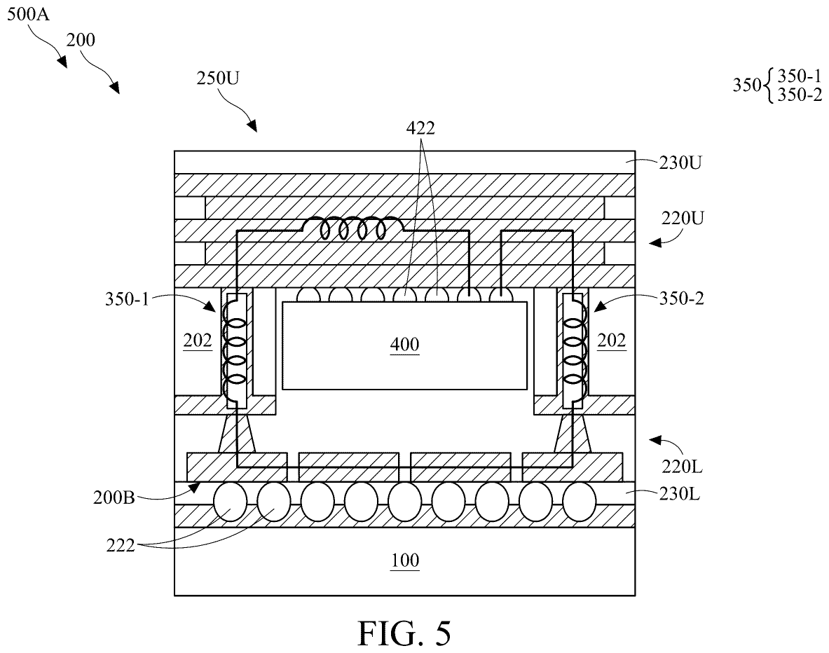

FIG. 1 is a schematic cross-sectional view of a substrate 200 of a semiconductor package 500 in accordance with some embodiments of the disclosure. FIGS. 2A and 2B are schematic plan views of a portion of the substrate 200 of the semiconductor package 500 of FIG. 1, showing one or more inductors 250 and conductive traces 208 embedded in the substrate 200. For illustration, the elements above the inductors 250 (e.g., solder mask layers 230) are omitted in FIGS. 2A and 2B. FIGS. 3A and 3B are perspective views of a portion 270 of the substrate 200 of FIGS. 2A and 2B. For illustration, the elements except for the inductor 250 of FIGS. 2A and 2B (e.g., an insulating layer 210) are omitted in FIGS. 3A and 3B. FIGS. 4A, 4B, 4C, 4D, 4E, 4F, 4G and 4H are enlarge views of FIGS. 2A and 2B, showing the arrangements of the conductive post and a conductive layer 308 of the inductor 250.

The semiconductor package 500 includes the substrate 200. For example, the substrate 200 may include a multi-layered package substrate. The substrate 200 may provide mechanical support and electrical connections between an integrated circuit (IC) chip (e.g., an integrated circuit (IC) chip 400 shown in FIGS. 5 to 8) and a base (e.g., a base 100 shown in FIGS. 5 to 8), for example a printed circuit board (PCB). In some embodiments, the substrate 200 may be a package substrate instead of a wafer or a wafer substrate. In some embodiments, the substrate 200 may be a printed circuit board (PCB). The substrate 200 may have various types including, for example, cored substrates, including thin core, thick core (e.g., laminate BT (bismaleimide-triazine resin) or FR-4 type fibrous board material), and laminate core. Alternatively, the cored package substrates, for example, can be built up layer by layer around a central core, with layers of conductive material (usually copper) separated by layers of insulating dielectric, with interlayer connections being formed with through holes or vias (microvias).

In some embodiments, the substrate 200 includes a core 202, redistribution layer (RDL) structures 220 (including redistribution layer (RDL) structures 220U and 220L). The substrate 200 further includes one or more inductors 250 (inductors 250 may include inductors 250U and 250L) embedded in the redistribution layer structures 220U and 220L.

As shown in FIG. 1, the core 202 has a top surface 202T and a bottom surface 202B. In some embodiments, the core 202 may be formed of polypropylene (PP), Pre-preg, FR-4 and/or other epoxy laminate material.

As shown in FIG. 1, the core 202 has holes TH embedded and passing through it. In addition, the substrate 200 may further includes through hole vias TV formed in the holes TH. In some embodiments, each of the through hole vias TV includes a conductive film 204 lining an inner wall of the hole TH. The conductive material film 204 in the hole TH may have a hollow pillar shape. Two terminals (not shown) of the conductive film 204 in each of the holes TH may be close to the top surface 202T and the bottom surface 202B of the core 202, respectively. In addition, the two terminals of the conductive film 204 in each of the holes TH may be exposed from the top surface 202T and the bottom surface 202B of the core 202, respectively. In some embodiments, the conductive film 204 includes copper or nickel-copper.

As shown in FIG. 1, each of the through hole vias TV may further includes a non-conductive material 205 filling the remaining spaces of the holes TH and surrounded by the conductive film 204. In some embodiments, the non-conductive material 205 includes epoxy resin, such as an ink.

As shown in FIG. 1, the redistribution layer structures 220U and 220L are disposed on the top surface 202T and the bottom surface 202B of the core 202. In addition, the redistribution layer structures 220U and 220L are connected to (or coupled to) the conductive material 204 in the holes TH. In some embodiments, the redistribution layer structures 220U and 220L include conductive traces 208 (including conductive traces 208U and 208L), and vias 212 (including vias 212U and 212L) disposed in insulating layers 210 (including insulating layers 210U, 210L). It should be noted that the number of vias 212U, 212L, the number of conductive traces 208U, 208L and the number of insulating layers 210U, 210L shown in FIG. 1 are only an example and is not a limitation to the present disclosure.

In some embodiments, the conductive traces 208U include conductive traces 208U-1, 208U-2, 208U-3 and 208U-4 located from the innermost level (closest to the top surface 202T of the core 202) to the outermost level of the substrate 200. Similarly, the conductive traces 208L include conductive traces 208L-1, 208L-2, 208L-3 and 208L-4 located from the innermost level (closest to the bottom surface 200B of the core 202) to the outermost level of the substrate 200.

The conductive traces 208U and 208L may overlap the through hole vias TV. More specifically, the conductive traces 208U-1, 208L-1 is formed directly on the top surface 202T and the bottom surface 202B of the core 202. In some embodiments, the conductive traces 208U-1 and 208L-1 may cover the holes TH, the conductive films 204 lining the inner walls of the holes TH and the non-conductive material 205 filling the holes TH. For example, the conductive traces 208U-1 and 208L-1 may fully cover the holes TH and the conductive material 204 and the non-conductive material 205 in the holes TH. In addition, the conductive traces 208U-1 and 208L-1 may be connected (coupled) to the conductive material 204 lining the inner wall walls of the holes TH. In addition, the conductive traces 208U-2, 208U-3 and 208U-4 are located directly over the conductive trace 208U-1. The conductive traces 208L-2, 208L-3 and 208L-4 are located directly over the conductive trace 208L-1.

As shown in FIG. 1, the redistribution layer structures 220U and 220L may further include conductive layers 308 (including conductive layers 308U and 308L) located at the same level with the corresponding conductive traces 208 (including conductive traces 208U and 208L). In some embodiments, the conductive layers 308U include conductive layers 308U-1, 308U-2, 308U-3 and 308U-4 located at the same level with the conductive traces 208U-1, 208U-2, 208U-3 and 208U-4. The conductive layers 308L include conductive layers 308L-1, 308L-2, 308L-3 and 308L-4 located at the same level with the conductive traces 208L-1, 208L-2, 208L-3 and 208L-4.

The conductive layers 308U and 308L may be located offset from the through hole vias TV. More specifically, the conductive layers 308U-1, 308L-1 is formed directly on the top surface 202T and the bottom surface 202B of the core 202. In some embodiments, the conductive layers 308U-1 and 308L-1 may be formed without overlapping the through hole vias TV. In addition, the conductive layers 308U-2, 308U-3 and 308U-4 are located directly over the conductive trace 308U-1. The conductive layers 308L-2, 308L-3 and 308L-4 are located directly over the conductive trace 308L-1.

In some embodiments, the redistribution layer (RDL) structures 220U and 220L may further include conductive planes (also called ground planes) (not shown) located at the same level with the corresponding conductive traces 208U and 208L (or the corresponding conductive layers 308U and 308L).

The insulating layers 210U and 210L are formed on the top surface 202T and the bottom surface 202B of the core 202, respectively. In addition, the insulating layers 210U and 210L may be disposed on the corresponding conductive traces 208U and 208L, respectively. In addition, the insulating layers 210U and 210L may partially cover the conductive traces 208U and 208L, the holes TH, the conductive material 204 lining the inner walls of the holes TH and the non-conductive material 205 filling the holes TH.

In some embodiments, the insulating layers 210U include insulating layers 210U-1, 210U-2 and 210U-3 located from the innermost level (closest to the top surface 202T of the core 202) to the outermost level of the substrate 200. Similarly, the insulating layers 210L include insulating layers 210L-1, 210L-2 and 210L-3 located from the innermost level (closest to the bottom surface 202B of the core 202) to the outermost level of the substrate 200.

The vias 212U and 212L are disposed in the insulating layers 210U and 210L. The vias 212U and 212L may be formed passing through the corresponding insulating layers 210U and 210L to be coupled to the corresponding conductive traces 208U and 208L.

In some embodiments, the vias 212U include vias 212U-1, 212U-2 and 212U-3 located from the innermost level (closest to the top surface 202T of the core 202) to the outermost level of the substrate 200. Similarly, the vias 212L include vias 212L-1, 212L-2 and 212L-3 located from the innermost level (closest to the bottom surface 202B of the core 202) to the outermost level of the substrate 200.

As shown in FIG. 1, the vias 212U-1 passing through the insulating layer 210U-1 are coupled to the conductive traces 208U-1 and 208U-2 directly on the through hole vias TV. Similarly, the vias 212L-1 passing through the insulating layer 210L-1 are coupled to the conductive traces 208L-1 and 208L-2 directly on the through hole vias TV. The vias 212U-2 passing through the insulating layer 210U-2 are coupled to the conductive traces 208U-2 and 208U-3. Similarly, the vias 212L-2 passing through the insulating layer 210L-2 are coupled to the conductive traces 208L-2 and 208L-3. The vias 212U-3 passing through the insulating layer 210U-3 are coupled to the conductive traces 208U-3 and 208U-4. Similarly, the vias 212L-3 passing through the insulating layer 210L-3 are coupled to the conductive traces 208L-3 and 208L-4.

As shown in FIG. 1, the redistribution layer structures 220U and 220L may further include conductive posts 312 (including conductive posts 312U and 312L) located at the same level with the corresponding vias 212 (including vias 212U and 212L). In some embodiments, the conductive posts 312U include conductive posts 312U-1, 312U-2 and 312U-3 located at the same level with the vias 212U-1, 212U-2 and 212U-3. The conductive posts 312L include conductive posts 312L-1, 312L-2 and 312L-3 located at the same level with the vias 212L-1, 212L-2 and 212L-3.

As shown in FIG. 1, the conductive post 312U-1 passing through the insulating layer 210U-1 is coupled to the conductive layers 308U-1 and 308U-2 offset from the through hole vias TV. Similarly, the conductive post 312L-1 passing through the insulating layer 210L-1 is coupled to the conductive layers 308L-1 and 308L-2 directly on the through hole vias TV. The conductive post 312U-2 passing through the insulating layer 210U-2 is coupled to the conductive layers 308U-2 and 308U-3. Similarly, the conductive post 312L-2 passing through the insulating layer 210L-2 is coupled to the conductive layers 308L-2 and 308L-3. The conductive post 312U-3 passing through the insulating layer 210U-3 is coupled to the conductive layers 308U-3 and 308U-4. Similarly, the conductive post 312L-3 passing through the insulating layer 210L-3 is coupled to the conductive layers 308L-3 and 308L-4.

In some embodiments, the conductive traces 208U, 208L, the conductive layers 308U, 308L, the vias 212U, 212L, and the conductive posts 312U, 312L include a conductive material, such as metals comprising copper, gold, silver, or other applicable metals. For example, the conductive traces 208U and 208L may be copper traces 208U and 208L. The conductive layers 308U and 308L may be copper layers 308U and 308L. The vias 212U and 212L may be copper vias 212U and 212L. The conductive posts 312U and 312L may be copper posts 312U and 312L. In some embodiments, the insulating layers 226 in the redistribution layer structures 220U and 220L include BT (bismaleimide-triazine resin) polypropylene (PP) or Pre-preg.

As shown in FIG. 1, the semiconductor package 500 further includes solder mask layers 230 (including solder mask layers 230U and 230L) disposed over the corresponding redistribution layer structures 220U and 220L. In some embodiments, the solder mask layers 230U and 230L may partially cover the conductive traces 208U and 208L and the conductive layers 308U and 308L on the outermost insulating layers 210U and 210L of the redistribution layer structures 220U and 220L. In addition, the solder mask layers 230U and 230L may have openings (not shown) to expose corresponding conductive pads (not shown) coupled to the conductive traces 208U and 208L and the conductive layers 308U and 308L. In some embodiments, the solder mask layers 230U and 230L may include an epoxy resin.

In the substrate 200, the conductive layers 308U-1, 308U-2, 308U-3 and 308U-4 and the conductive posts 312U-1, 312U-2 and 312U-3 may form the inductor 250U embedded in the redistribution layer structure 220U. The conductive layers 308L-1, 308L-2, 308L-3 and 308L-4 and the conductive posts 312L-1, 312L-2 and 312L-3 may form the inductor 250L embedded in the redistribution layer structure 220L. As shown in FIGS. 2A and 2B, the inductor 250 may optionally include a magnetic core 260 disposed inside a coil formed by the conductive layers 308 and the conductive posts 312.

In some embodiments, the conductive posts 312 located at different levels of the substrate 200 may be formed of a single conductive post as shown in FIGS. 4A to 4C or a plurality of sub-portions as shown in FIGS. 4D to 4H.

In some embodiments, the single conductive post 312 (including conductive posts 312A (FIG. 4A), 312B (FIG. 4B) and 312C (FIG. 4C)) and the single via 212 at the same level of the substrate 200 may have different size in a plan view. For example, the single conductive post 312 and the single via 212 at the same level of the substrate 200 may have different areas in a plan view, and/or the single conductive post 312 and the single via 212 at the same level of the substrate 200 may have different width or diameter in a plan view. In some embodiments, the size of the single conductive post 312 is greater than the size of the single via 212. For example, the width or the diameter of the single conductive post 312 is greater than the width or the diameter of the single via 212, and/or the area of the single conductive post 312 is greater than the area of the single via 212.

In some embodiments, the single conductive post 312 and the single via 212 have different shapes in the plan view. For example, in the plan view as shown in FIG. 2, the via 212 is circular shape. In the plan view as shown in FIG. 2, the conductive post 312 may be continuously arranged along the conductive layer 308. The conductive post 312 and the conductive layer 308 may have a one-to-one relationship. In addition, the conductive post 312 and the conductive layer 308 have similar shapes (or similar outer contour) in the plan view as shown in FIG. 2.

As shown in FIG. 4A, the conductive post 312A may be strip-shaped. The conductive post 312A may be continuously arranged in the long axis direction and/or the short axis direction of the conductive layer 308. As shown in FIG. 4B, the conductive post 312B may be grid-strip shaped. In some embodiments, the conductive post 312B may be provided with a plurality of through holes (as shown in the dashed rectangular box in FIG. 4B) relative to the conductive post 312A. The through holes may be hollow or filled with insulating material. As shown in FIG. 4C, the conductive post 312C may be chain-shaped. In some embodiments, the conductive post 312C may be provided with a plurality of through holes (as shown in the dashed rectangular box in FIG. 4C) arranged only in the long axis direction of the conductive layer 308 relative to the conductive post 312A. Each of the plurality of through holes spaced apart from each other may be hollow or filled with insulating material. In the short axis direction (e.g., the direction 11) of the conductive layer 308, the width WA of the conductive post 312A, the width WB of the conductive post 312B, and the width WC of the conductive post 312C may be greater than or equal to half the width W308 of the conductive layer 308.

In some embodiments, the conductive post 312 may include sub-portions 312S (including sub-portions 312SD (FIG. 4D), 312SE (FIG. 4E), 312SF (FIG. 4F), 312SG (FIG. 4G) and 312SH (FIG. 4H) arranged side-by-side and separated from each other. The separated sub-portions may be discontinuously arranged in the long axis direction and/or the short axis direction of the conductive layer 308. For example, separated sub-portions may be discontinuously arranged in the long axis direction and/or the short axis direction of the conductive layer 308. The sub-portions of the conductive post 312 and the conductive layer 308 may have multi-to-one relationship.

In some embodiments, the single sub-portion 312S of the conductive post 312 and the single via 212 at the same level of the substrate 200 may have different areas in a plan view. For example, in the plan view as shown in FIG. 2B, the area A3 of the single sub-portion 312S of the conductive post 312 is greater than the area A2 of the single via 212.

For example, the conductive post 312 may include strip-shaped sub-portions 312SD (FIG. 4D), 312SE (FIG. 4E) or 312SF (FIG. 4F) discontinuously arranged in the long axis direction of the conductive layer 308. As shown in FIGS. 4D and 4E, the long axis direction (e.g., the direction 10) of the sub-portions 312SD and 312SE of the conductive post 312 is substantially parallel to the long axis direction (e.g., the direction 10) of the conductive layer 308. In the short axis direction (e.g., the direction 11) of the conductive layer 308, the width WD of the sub-portions 312SD may be greater than half the width W308 of the conductive layer 308. In addition, the width WE of the sub-portions 312SE may be smaller than half the width W308 of the conductive layer 308. Therefore, the sub-portions 312SD may be arranged side-by-side only in the long axis direction (e.g., the direction 10) of the conductive layer 308. The sub-portions 312SE may be arranged side-by-side in the long axis direction (e.g., the direction 10) and the short axis direction (e.g., the direction 11) of the conductive layer 308.

In some embodiments, the sub-portions 312SE may be discontinuously arranged in the short axis direction (e.g., the direction 11) of the conductive layer 308, but each of the sub-portions 312SE continuously arranged in the long axis direction (e.g., the direction 10) of the conductive layer 308. Therefore, the sub-portions 312SE may be arranged side-by-side only in the short axis direction (e.g., the direction 11) of the conductive layer 308.

As shown in FIG. 4F, the long axis direction (e.g., the direction 11) of the sub-portions 312SF of the conductive post 312 is substantially perpendicular to the long axis direction (e.g., the direction 10) of the conductive layer 308. In the short axis direction (e.g., the direction 11) of the conductive layer 308, the width WF of the sub-portions 312SF may be greater than half the width W308 of the conductive layer 308. Therefore, the sub-portions 312SF may be arranged side-by-side only in the long axis direction (e.g., the direction 10) of the conductive layer 308. Alternatively, the width WF of the sub-portions 312SF may be smaller than half the width W308 of the conductive layer 308. Therefore, the sub-portions 312SF may be arranged side-by-side in the long axis direction (e.g., the direction 10) and the short axis direction (e.g., the direction 11) of the conductive layer 308.

As shown in FIG. 4G, the conductive post 312 may include grid-shaped sub-portions 312SG discontinuously arranged in the long axis direction of the conductive layer 308. The long axis direction (e.g., the direction 10) of the sub-portions 312SG of the conductive post 312 is substantially parallel to the long axis direction (e.g., the direction 10) of the conductive layer 308. In the short axis direction (e.g., the direction 11) of the conductive layer 308, the width WG of the sub-portions 312SG may be greater than half the width W308 of the conductive layer 308. Therefore, the sub-portions 312SG may be arranged side-by-side only in the long axis direction (e.g., the direction 10) of the conductive layer 308. In some embodiments, the sub-portion 312SG may be provided with a plurality of through holes (as shown in the dashed rectangular box in FIG. 4G) relative to the sub-portion 312SD. The through holes may be hollow or filled with insulating material. The sub-portions 312SE may be arranged side-by-side in the long axis direction (e.g., the direction 10) and the short axis direction (e.g., the direction 11) of the conductive layer 308.

In some embodiments, if the width WG of the sub-portions 312SG is smaller than half the width W308 of the conductive layer 308. The sub-portions 312SG may be discontinuously arranged in the short axis direction (e.g., the direction 11) of the conductive layer 308, but each of the sub-portions 312SG continuously arranged in the long axis direction (e.g., the direction 10) of the conductive layer 308. Therefore, the sub-portions 312SG may be arranged side-by-side only in the short axis direction (e.g., the direction 11) of the conductive layer 308. Alternatively, the sub-portions 312SG may be discontinuously arranged in the long axis direction (e.g., the direction 10) and the short axis direction (e.g., the direction 11) of the conductive layer 308. Therefore, the sub-portions 312SG may be arranged side-by-side in the long axis direction (e.g., the direction 10) and the short axis direction (e.g., the direction 11) of the conductive layer 308.

As shown in FIG. 4H, the conductive post 312 may include ring shaped sub-portions 312SH. In some embodiments, each of the sub-portions 312SH may be provided with a single through hole (as shown in the dashed rectangular box in FIG. 4H) relative to the sub-portion 312SD. The through holes may be hollow or filled with insulating material. The long axis direction (e.g., the direction 10) of the sub-portions 312SH of the conductive post 312 is substantially parallel to the long axis direction (e.g., the direction 10) of the conductive layer 308. In the short axis direction (e.g., the direction 11) of the conductive layer 308, the width WH of the sub-portions 312SH may be greater than half the width W308 of the conductive layer 308. Therefore, the sub-portions 312SH may be arranged side-by-side only in the long axis direction (e.g., the direction 10) of the conductive layer 308.

In some embodiments, if the width WH of the sub-portions 312SH is smaller than half the width W308 of the conductive layer 308. The sub-portions 312SH may be discontinuously arranged in the short axis direction of the conductive layer 308, but each of the sub-portions 312SH continuously arranged in the long axis direction of the conductive layer 308. Therefore, the sub-portions 312SH may be arranged side-by-side only in the short axis direction (e.g., the direction 11) of the conductive layer 308. Alternatively, the sub-portions 312SH may be discontinuously arranged in the long axis direction (e.g., the direction 10) and the short axis direction (e.g., the direction 11) of the conductive layer 308. Therefore, the sub-portions 312SH may be arranged side-by-side in the long axis direction (e.g., the direction 10) and the short axis direction (e.g., the direction 11) of the conductive layer 308.

In some embodiments, opposite edges of the single conductive post 312 (or opposite edges of the single sub-portion 312S of the conductive post 312) are substantially parallel to corresponding opposite edges of the conductive layer 308, as shown in FIGS. 2A, 2B and 4A to 4H.

In some embodiments, the conductive posts 312U-1, 312U-2 and 312U-3 of the inductor 250U and the conductive posts 312L-1, 312L-2 and 312L-3 of the inductor 250L may be formed of any combination of the single conductive posts 312A (FIG. 4A), 312B (FIG. 4B) and 312C (FIG. 4C) and/or the sub-portions 312SD (FIG. 4D), 312SE (FIG. 4E), 312SF (FIG. 4F), 312SG (FIG. 4G) and 312SH (FIG. 4H).

In some embodiments, the inductor 250 formed in the redistribution layer structure 220 may be coupled other magnetic core inductors and/or integrated passive devices disposed in the substrate 200. FIGS. 5, 6, 7 and 8 are schematic cross-sectional views of the semiconductor package 500 (including semiconductor packages 500A, 500B, 500C and 500D) in accordance with some embodiments of the disclosure, showing the connections between the inductor 250 (including inductors 250U and 250L) of FIG. 1 and other inductors of the semiconductor package 500.

As shown in FIG. 5, the semiconductor package 500A may include the substrate 200 having the inductor 250U in the redistribution layer structure 220U, the integrated circuit (IC) chip 400 and the base 100. In this embodiment, the integrated circuit (IC) chip 400 is disposed embedded in the core 202 of the substrate 200. The base 100 is disposed on the bottom surface 200B (also called the base-attached surface) of the substrate 200. In addition, the substrate 200 may further include inductors 350 (e.g., magnetic core inductors) (including inductors 350-1 and 350-2) disposed passing through the core 202. The inductors 250U, 350-1 and 350-2 may be sequentially connected in series. More specifically, the inductor 250U is coupled to the inductor 350-1 by the redistribution layer structure 220U. The inductor 350-1 is coupled to the inductor 350-2 by the redistribution layer structure 220L. The inductor 350-1 is coupled between the inductor 250U and the inductor 350-2.

As shown in FIG. 5, the semiconductor package 500A may further include conductive bumps 422 attached to the bottom of the redistribution layer structure 220U. The integrated circuit (IC) chip 400 is coupled to the redistribution layer structure 220U by the conductive bumps 422. In addition, the series connected inductors 250U, 350-1 and 350-2 are coupled to the integrated circuit (IC) chip 400 by the conductive bumps 422.

As shown in FIG. 5, the semiconductor package 500A may further include conductive bumps 222 attached to the bottom surface 200B of the substrate 200. The base 100 is coupled to the redistribution layer structure 220L by the conductive bumps 222.

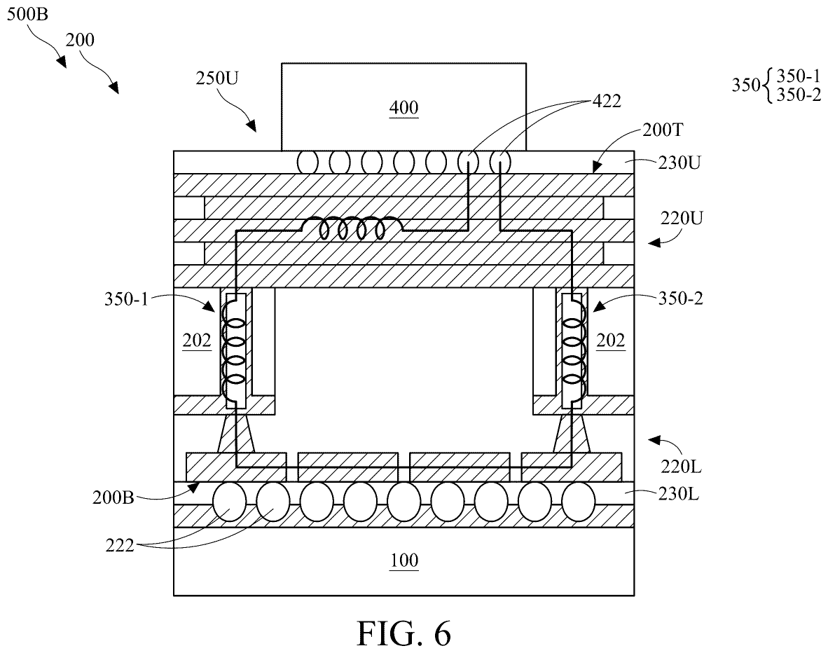

FIG. 6 is a schematic cross-sectional view of the semiconductor package 500B in accordance with some embodiments of the disclosure. Elements of the embodiments hereinafter, that are the same or similar as those previously described with reference to FIG. 5, are not repeated for brevity. As shown in FIGS. 5 and 6, the difference between the semiconductor package 500A and the semiconductor package 500B at least includes that the integrated circuit (IC) chip 400 and the conductive bumps 422 are disposed on the top surface 200T (also called the chip-attached surface) the substrate 200. In addition, the series connected inductors 250U, 350-1 and 350-2 are coupled to the integrated circuit (IC) chip 400 by the conductive bumps 422 attached to the top surface of the substrate 200.

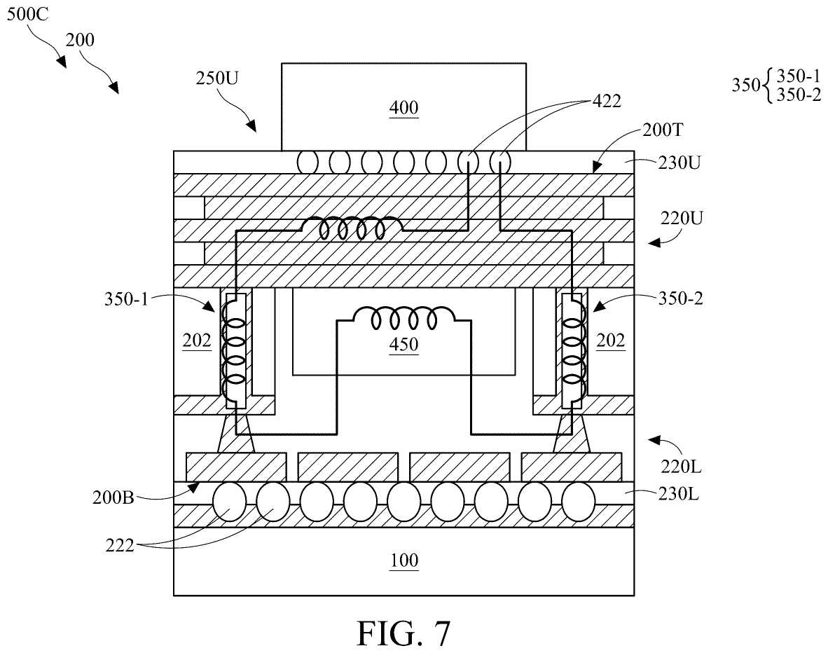

FIG. 7 is a schematic cross-sectional view of the semiconductor package 500C in accordance with some embodiments of the disclosure. Elements of the embodiments hereinafter, that are the same or similar as those previously described with reference to FIGS. 5 and 6, are not repeated for brevity. As shown in FIGS. 6 and 7, the difference between the semiconductor package 500B and the semiconductor package 500C at least includes that the semiconductor package 500C may further include an integrated passive device 450 disposed embedded in the core 202 of the substrate 200. The inductor 250U, the inductor 350-1, the integrated passive device 450, and the inductor 350-2 may be sequentially connected in series. More specifically, the inductor 250U is coupled to the inductor 350-1 by the redistribution layer structure 220U. The inductor 350-1 is coupled to the integrated passive device 450 by the redistribution layer structure 220L. The integrated passive device 450 is coupled to the inductor 350-2 by the redistribution layer structure 220L. The integrated passive device 450 is coupled between and the inductors 350-1 and 350-2. In some embodiments, the integrated passive device 450 may include an integrated inductor.

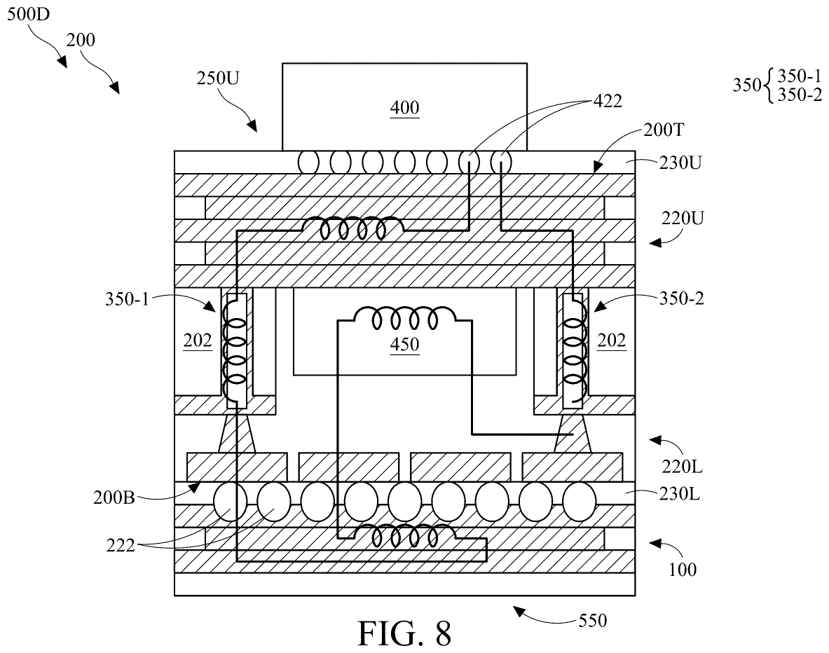

FIG. 8 is a schematic cross-sectional view of the semiconductor package 500D in accordance with some embodiments of the disclosure. Elements of the embodiments hereinafter, that are the same or similar as those previously described with reference to FIGS. 5 to 7, are not repeated for brevity. As shown in FIGS. 7 and 8, the difference between the semiconductor package 500C and the semiconductor package 500D at least includes that the semiconductor package 500D may further include an inductor 550 embedded in the base 100. In some embodiments, the inductor 250U and the inductor 550 may have the same or similar structure. For example, the inductor 550 may be formed by alternately arranged conductive layers and conductive posts of a redistribution structure of the base 100. The inductor 250U, the inductor 350-1, the integrated passive device 450, the inductor 550, and the inductor 350-2 may be sequentially connected in series. More specifically, the inductor 250U is coupled to the inductor 350-1 by the redistribution layer structure 220U. The inductor 350-1 is coupled to the inductor 550 by the redistribution layer structure 220L and the conductive bumps 222. The inductor 550 is coupled to the integrated passive device 450 by the conductive bumps 222 and the redistribution layer structure 220L. The integrated passive device 450 is coupled to the inductor 350-2 by the redistribution layer structure 220L. The inductor 250U is coupled between and the inductors 350-1 and the integrated passive device 450.

Compared with the conventional inductor formed by parallel wirings connected by vias, the inductor 250 of the semiconductor package 500 may have lower resistance value, thereby reducing power losses, improving the overall efficiency, thermal issues and performance of the circuit. In addition, the inductor 250 of the semiconductor package 500 may have superior direct current resistance (DCR) properties in same area, improved alternating current resistance (ACR) properties and thermal stability.

Methods for forming the substrate 200 of the semiconductor package 500 are described below.

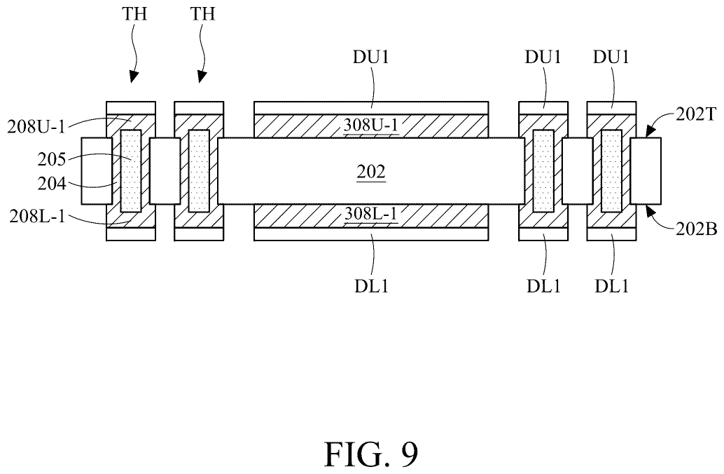

FIGS. 9, 10, 11, 12, 13 and 14 are schematic cross-sectional views at intermediate stages of forming the substrate 200 of the semiconductor package 500 of FIG. 1 in accordance with some embodiments of the disclosure.

Referring to FIG. 9, a core 202 (e.g., copper clad laminate, CCL) is provided. Next, a drilling process (e.g., mechanical drilling) is performed to form the holes TH passing through the core 202. Next, a desmear processes is performed to remove the residues in the holes TH. Next, a plating process and subsequent filling process are performed to form a conductive material (not shown) and the non-conductive material 205. The conductive material may be formed lining the inner walls of the holes TH and extending to cover the top surface 202T and the bottom surface 202B of the core 202. The non-conductive material 205 filling the remaining spaces of the holes TH. In some embodiments, the plating process may include chemical plating or electro-less plating. Next, a desmear processes is performed to remove the residues on the core 202.

Next, a lamination process and a subsequent DES (developing, etching, and stripping) process are performed to form patterned dry films (patterned insulating films) DU1 and DL1 on the top surface 202T and the bottom surface 202B of the core 202.

Next, a patterning process is performed to remove the conductive material not covered by the patterned dry films (patterned insulating films) DU1 and DL1. After the patterning process is performed, the conductive traces 208U-1 and the conductive layer 308U-1 are formed on the top surface 202T of the core 202. At the same time, the conductive traces 208L-1 and the conductive layer 308L-1 are formed on the bottom surface 202B of the core 202. Next, a stripping process is performed to remove the patterned dry films (patterned insulating films) DU1 and DL1.

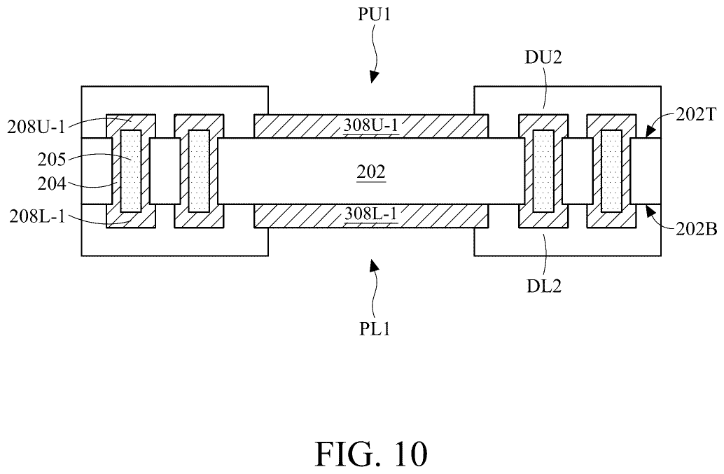

Next, referring to FIG. 10, a lamination process and a subsequent DES (developing, etching, and stripping) process are performed to form patterned dry films DU2 and DL2 on the top surface 202T and the bottom surface 202B of the core 202. The patterned dry film DU2 may fully cover the conductive traces 208U-1. In addition, the patterned dry film DU2 may have an opening PU1 to expose a portion of the conductive layer 308U-1. Similarly, the patterned dry film DL2 may fully cover the conductive traces 208U-1. In addition, the patterned dry film DL2 may have an opening PL1 to expose a portion of the conductive layer 308L-1. In some embodiments, the opening PU1 and the opening PL1 may be formed by etching process. For example, after the formed dry film (which will form the patterned dry film DU2 in the subsequent process) fully covers the conductive traces 208U-1 and the conductive layer 308U-1, a mask is used for exposure, and then an etching process is used to etch and form an opening PU1, thereby obtaining a patterned dry film DU2 with an opening PUL. The above method is completely different from the method of forming vias and other openings (such as the vias 212 and the openings PU2-2) using drilling process (e.g., laser drilling process). The opening PL1 and the patterned dry film DL2 are formed in a manner substantially the same as or similar to the opening PU1 and the patterned dry film DU2. In some embodiments, the dry film may also be called the insulating film, and the patterned dry film may also be called the patterned insulating film.

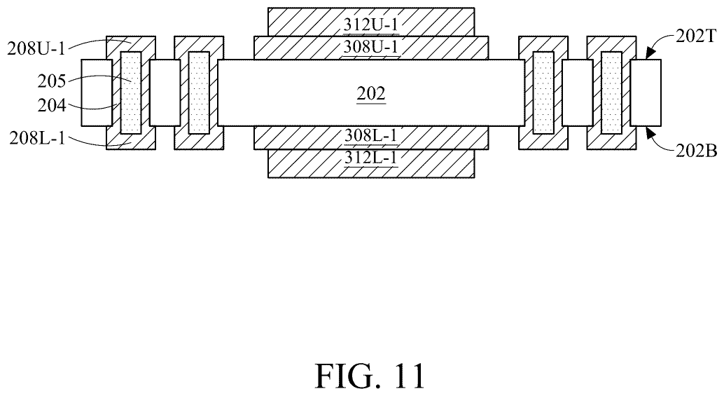

Next, referring to FIG. 11, a plating process is performed to form conductive posts 312U-1 and 312L-1 on the conductive layer 308U-1 and 308L-1 and fill (up) the openings PU1 and PL1 (FIG. 10). After forming the conductive posts 312U-1 and 312L-1, a stripping process is performed to remove the patterned dry films DU2 and DL2. Therefore, the conductive post(s) 312U-1 is formed before the openings PU2-2, the conductive trace 208U-2 and the vias 212U-1, and the conductive post(s) 312L-1 is formed before the openings PL2-2, the conductive trace 208L-2 and the vias 212L-1.

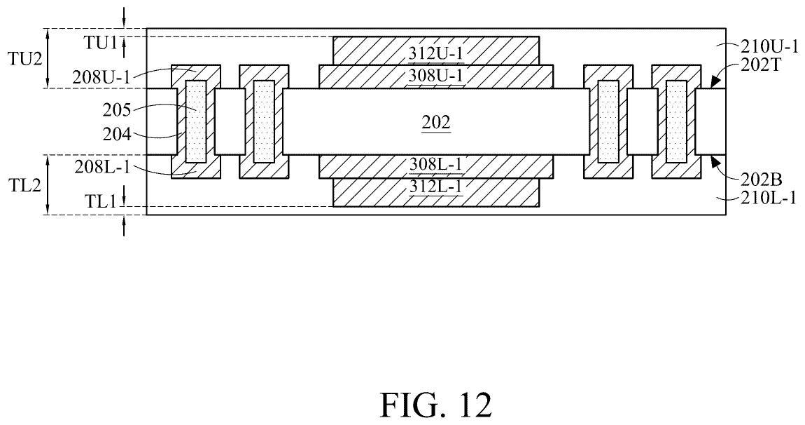

Next, referring to FIG. 12, a lamination process is performed to form insulating layers 210U-1 and 210L-1 on the top surface 202T and the bottom surface 202B of the core 202. The insulating layer 210U-1 may cover the conductive traces 208U-1, the conductive layer 308U-1 and the conductive post 312U-1. In some embodiments, the thickness TU1 of the insulating layer 210U-1 directly on the conductive post 312U-1 is less than the thickness TU2 of the insulating layer 210U-1 directly on the conductive traces 208U-1. The thickness TL1 of the insulating layer 210L-1 directly on the conductive post 312L-1 is less than the thickness TL2 of the insulating layer 210L-1 directly on the conductive traces 208L-1.

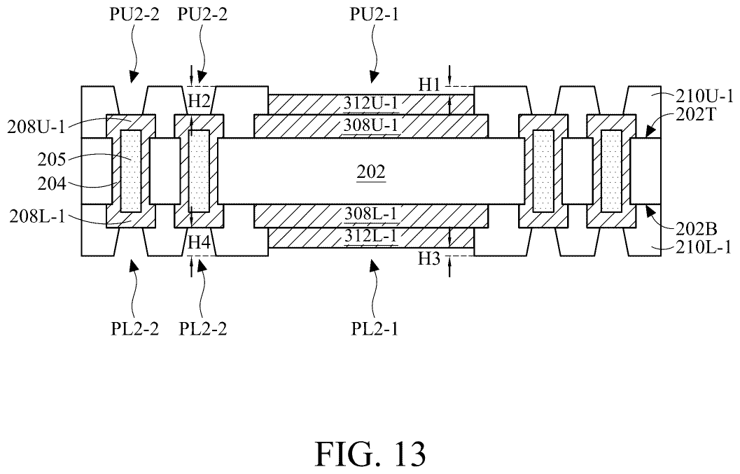

Next, referring to FIG. 13, a drilling process (e.g., laser drilling) is performed to form openings PU2-1 and PU2-2 passing through the insulating layer 210U-1 and openings PL2-1 and PL2-2 passing through the insulating layer 210L-1. The conductive post 308U-1 is exposed from the opening PU2-1. In addition, the conductive traces 208U-1 are exposed from the openings PU2-2. The conductive post 308L-1 is exposed from the opening PL2-1. In addition, the conductive traces 208L-1 are exposed from the openings PL2-2. In some embodiments, the opening PU2-1 is shallower than the opening PU2-2. For example, the depth H1 of the opening PU2-1 exposing the conductive post 312U-1 is less than the depth H2 of the opening PU2-2 exposing the conductive traces 208U-1. The depth H3 of the opening PL2-1 exposing the conductive post 312L-1 is less than the depth H4 of the opening PL2-2 exposing the conductive traces 208L-1. In some embodiments, the size of the opening PU1 is greater than the size of one of the openings PU2-2. For example, the width or the diameter of the opening PU1 is greater than the width or the diameter of one of the openings PU2-2, and/or the area of the opening PU1 is greater than the area of one of the openings PU2-2. In some embodiments, the size of the opening PL1 is greater than the size of one of the openings PL2-2. For example, the width or the diameter of the opening PL1 is greater than the width or the diameter of one of the openings PL2-2, and/or the area of the opening PL1 is greater than the area of one of the openings PL2-2. In some embodiments, the openings PU1 and PL1 are formed before the openings PU2-2 and PL2-2. In some embodiments, the conductive posts 312U-1 and 312L-1 and the vias 212U-1 and 212L-1 are formed in different steps. In some embodiments, the conductive posts 312U-1 and 312L-1 and the vias 212U-1 and 212L-1 are formed in different steps. In some embodiments, the openings PU1 and PL1 are formed before the openings PU2-2 and PL2-2. In some embodiments, the conductive posts 312U-1 and 312L-1 are formed before the vias 212U-1 and 212L-1.

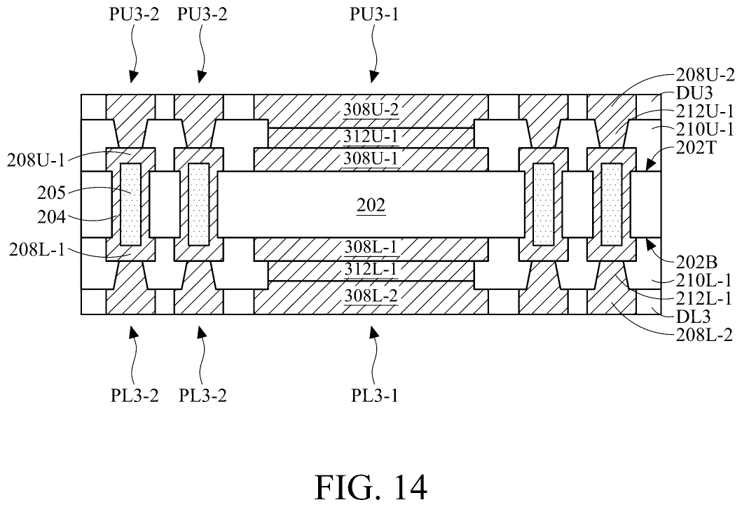

Next, referring to FIG. 14, a lamination process and a subsequent DES (developing, etching, and stripping) process are performed to form patterned dry films DU3 and DL3 on the top surface 202T and the bottom surface 202B of the core 202. The patterned dry films DU3 may have openings PU3-1 and PU3-2 aligned with the corresponding openings PU2-1 and PU2-2 (FIG. 13). In addition, the patterned dry films DL3 may have openings PL3-1 and PL3-2 aligned with the corresponding openings PL2-1 and PL2-2 (FIG. 13). In some embodiments, the size of the conductive post 312U-1 is greater than the size of one of the vias 212U-1. For example, the width or the diameter of the conductive post 312U-1 is greater than the width or the diameter of one of the vias 212U-1, and/or the area of the conductive post 312U-1 is greater than the area of one of the vias 212U-1. In some embodiments, the size of the conductive post 312L-1 is greater than the size of one of the vias 212L-1. For example, the width or the diameter of the conductive post 312L-1 is greater than the width or the diameter of one of the vias 212L-1, and/or the area of the conductive post 312L-1 is greater than the area of one of the vias 212L-1.

Next, a plating process is performed to form conductive traces 208U-2 and 208L-2, vias 212U-1 and 212L-1 and conductive layers 308U-2 and 308L-2. The conductive layer 308U-2 may be formed filling the openings PU3-1 passing through the patterned dry film DU3 and the openings PU2-1 passing through the insulating layer 210U-1. The conductive layer 308U-2 is connected (coupled) to the conductive post 312U-1. The vias 212U-1 may be formed in the openings PU2-2 and pass through the insulating layer 210U-1. The vias 212U-1 are connected (coupled) to the corresponding conductive traces 208U-1. In addition, the conductive traces 208U-2 may be formed in the openings PU3-2 passing through the patterned dry film DU3 are connected (coupled) to the corresponding vias 212U-1. In some embodiments, the conductive trace 208U-2 is formed integrated with the vias 212U-1.

The conductive layer 308L-2 may be formed filling the openings PL3-1 passing through the patterned dry film DL3 and in the openings PL2-1 passing through the insulating layer 210L-1. The conductive layer 308L-2 is connected (coupled) to the conductive post 312L-1. The vias 212L-1 may be formed in the openings PL2-2 and pass through the insulating layer 210L-1. The vias 212L-1 are connected (coupled) to the corresponding conductive traces 208L-1. In addition, the conductive traces 208L-2 may be formed in the openings PL3-2 passing through the patterned dry film DL3 are connected (coupled) to the corresponding vias 212L-1. In some embodiments, the conductive trace 208U-2 is formed integrated with the vias 212L-1.

After the conductive traces 208U-2 and 208L-2, the vias 212U-1 and 212L-1 and the conductive layers 308U-2 and 308L-2 are formed, a stripping process is performed to remove the patterned dry films DU3 and DL3.

Next, referring to FIG. 1, the processes similar to those shown in FIGS. 10 to 14 are sequentially performed to form conductive posts 312U-2 and 312L-2 on the conductive layers 308U-2 and 308L-2, insulating layers 210U-2 and 210L-2 on the conductive traces 208U-2 and 208L-2, vias 212U-2 and 212L-2 passing through the insulating layers 210U-2, 210L-2, conductive traces 208U-3, 208L-3 and conductive layers 308U-3, 308L-3 on the insulating layers 210U-2, 210L-2. Next, the processes similar to those shown in FIGS. 10 to 14 are sequentially performed to form, conductive posts 312U-3 and 312L-3 on the conductive layers 308U-3 and 308L-3, insulating layers 210U-3 and 210L-3 on the conductive traces 208U-3 and 208L-3, vias 212U-3 and 212L-3 passing through the insulating layers 210U-3, 210L-3, conductive traces 208U-4, 208L-4 and conductive layers 308U-4, 308L-4 on the insulating layers 210U-3, 210L-3. After the aforementioned processes, redistribution layer structures 220U and 220L having the inductors 250U and 250L are formed on the top surface 202T and the bottom surface 202B of the core 202.

Next, still referring to FIG. 1, solder mask layers 230U and 230L are formed partially cover the conductive traces 208U-4 and 208L-4 and the conductive layers 308U-4 and 308L-4 on the outermost insulating layers 210U-3 and 210L-3 of the redistribution layer structures 220U and 220L. After the aforementioned processes, the semiconductor package 500 is formed.

Embodiments provide a semiconductor package and method for forming the same. The semiconductor package includes a substrate. The substrate includes a core and a redistribution layer structure. The redistribution layer structure is disposed on the core. The redistribution layer structure includes an inductor. The inductor includes a first conductive layer, a conductive post and a second conductive layer. The conductive post is disposed on the first conductive layer. The second conductive layer is disposed on the conductive post. The conductive post and a via of the redistribution layer structure are located at the same level. In a plan view, a first area of the conductive post is greater than a second area of the via.

In some embodiments, a first width or a first diameter of the conductive post is greater than a second width or a second diameter of the via.

In some embodiments, the conductive post and the via have different shapes in the plan view.

In some embodiments, the conductive post is rectangular-shaped, strip-shaped, grid-strip shaped, chain-shaped, fence-shaped, grid-shaped, or ring-shaped.

In some embodiments, opposite edges of the conductive post are substantially parallel to corresponding opposite edges of the first conductive layer or the second conductive layer.

In some embodiments, the conductive post is continuously arranged along the first conductive layer or the second conductive layer.

In some embodiments, in the plan view, the conductive post, the first conductive layer and the second conductive layer have similar shapes.

In some embodiments, the conductive post and the first conductive layer have a one-to-one relationship.

In some embodiments, the conductive post comprises sub-portions arranged side-by-side and separated from each other.

In some embodiments, a long axis direction of the sub-portions of the conductive post is substantially parallel to a long axis direction of the first conductive layer or the second conductive layer.

In some embodiments, a long axis direction of the sub-portions of the conductive post is substantially perpendicular to a long axis direction of the first conductive layer or the second conductive layer.

In some embodiments, the redistribution layer structure further includes a first conductive trace disposed on the core and coupled to the via. The first conductive layer and the first conductive trace are located at the same level.

In some embodiments, the redistribution layer structure further includes a second conductive trace disposed on and coupled to the via. The second conductive layer and the second conductive trace are located at the same level.

The method for forming a semiconductor package includes forming a first conductive layer and a first conductive trace on a core forming a first insulating film on the first conductive layer and the first conductive trace; forming a first opening in the insulating first film by etching process to form a first pattern insulating film; forming a conductive post on the first conductive layer and in the first opening; forming an insulating layer on the conductive post and the first conductive trace; forming a second opening in the insulating layer by drilling process to expose the first conductive trace; and forming a second conductive layer and a via in the second opening. The second conductive layer is connected to the conductive post, and the via is connected to the first conductive trace.

In some embodiments, the conductive post is formed before forming the via.

In some embodiments, the patterned insulating film on the core is formed before forming the conductive post, wherein the patterned insulating film fully covers the conductive trace and the first conductive layer is exposed by the first opening. The method for forming a semiconductor package further includes removing the patterned insulating film after forming the conductive post.

In some embodiments, the method for forming a semiconductor package further includes forming a third opening and a fourth opening passing through the insulating layer after forming the insulating layer. The conductive post is exposed from the third opening, and the first conductive trace is exposed from the fourth opening. The method for forming a semiconductor package further includes forming a second patterned insulating film on the insulating layer before forming the second conductive layer and the via. The second patterned insulating film has a fifth opening aligned with the third opening and a sixth opening aligned with the fourth opening.

In some embodiments, the third opening is shallower than the fourth opening.

In some embodiments, the second conductive layer is formed filling the third opening and the fifth opening, and the via is formed filling the fourth opening.

In some embodiments, the method for forming a semiconductor package further includes forming a second conductive trace filling the fifth opening of the second patterned insulating film.

In some embodiments, a first area of the conductive post is greater than a second area of the via in a plan view.

The inductor of the semiconductor package uses conductive post connected between parallel conductive layers at different levels. The conductive post may be a single structure continuously arranged along the first conductive layer and the second conductive layer. Alternatively, the conductive post may include separated sub-portions continuously arranged along the first conductive layer and the second conductive layer. The area of the continuous conductive post or the single sub-portion of the discontinuous conductive post is greater than the area of the via.at the same level of the substrate. The inductor of the semiconductor package may have lower resistance value and improved Q factor.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package comprising a substrate, comprising:
a core;
a redistribution layer structure disposed on the core; and
an inductor embedded in redistribution layer structure, wherein the inductor comprises:
a first conductive layer on the core;
a conductive post disposed on the first conductive layer; and
a second conductive layer disposed on the conductive post,
wherein the conductive post and a via of the redistribution layer structure are located at the same level, and in a plan view, a first area of the conductive post is greater than a second area of the via.

2. The semiconductor package as claimed in claim 1, wherein a first width or a first diameter of the conductive post is greater than a second width or a second diameter of the via.

3. The semiconductor package as claimed in claim 1, wherein the conductive post and the via have different shapes in the plan view.

4. The semiconductor package as claimed in claim 1, wherein the conductive post is rectangular-shaped, strip-shaped, grid-strip shaped, chain-shaped, fence-shaped, grid-shaped, or ring-shaped.

5. The semiconductor package as claimed in claim 1, wherein opposite edges of the conductive post are substantially parallel to corresponding opposite edges of the first conductive layer or the second conductive layer.

6. The semiconductor package as claimed in claim 1, wherein the conductive post is continuously arranged along the first conductive layer or the second conductive layer.

7. The semiconductor package as claimed in claim 1, wherein in the plan view, the conductive post, the first conductive layer and the second conductive layer have similar shapes.

8. The semiconductor package as claimed in claim 1, wherein the conductive post comprises sub-portions arranged side-by-side and separated from each other.

9. The semiconductor package as claimed in claim 8, wherein a long axis direction of the sub-portions of the conductive post is substantially parallel to a long axis direction of the first conductive layer or the second conductive layer.

10. The semiconductor package as claimed in claim 8, wherein a long axis direction of the sub-portions of the conductive post is substantially perpendicular to a long axis direction of the first conductive layer or the second conductive layer.

11. The semiconductor package as claimed in claim 1, wherein the redistribution layer structure further comprises:
a first conductive trace disposed on the core and coupled to the via, wherein the first conductive layer and the first conductive trace are located at the same level.

12. The semiconductor package as claimed in claim 1, wherein the redistribution layer structure further comprises:
a second conductive trace disposed on and coupled to the via, wherein the second conductive layer and the second conductive trace are located at the same level.

13. A method for forming a semiconductor package, comprising:
forming a first conductive layer and a first conductive trace on a core;
forming a first insulating film on the first conductive layer and the first conductive trace;
forming a first opening in the first insulating film by etching process to form a first patterned insulating film;
forming a conductive post on the first conductive layer and in the first opening;
forming an insulating layer on the conductive post and the first conductive trace;
forming a second opening in the insulating layer by drilling process to expose the first conductive trace; and
forming a second conductive layer on the insulating layer and a via in the second opening, wherein the second conductive layer is connected to the conductive post, and the via is connected to the first conductive trace.

14. The method for forming a semiconductor package as claimed in claim 13, wherein the conductive post is formed before forming the via.

15. The method for forming a semiconductor package as claimed in claim 13, wherein the patterned insulating film on the core is formed before forming the conductive post, wherein the patterned insulating film fully covers the conductive trace and the first conductive layer is exposed by the first opening; and
the method further comprises: removing the patterned insulating film after forming the conductive post.

16. The method for forming a semiconductor package as claimed in claim 13, further comprising:
forming a third opening and a fourth opening passing through the insulating layer after forming the insulating layer, wherein the conductive post is exposed from the third opening, and the first conductive trace is exposed from the fourth opening; and
forming a second patterned insulating film on the insulating layer before forming the second conductive layer and the via, wherein the second patterned insulating film has a fifth opening aligned with the third opening and a sixth opening aligned with the fourth opening.

17. The method for forming a semiconductor package as claimed in claim 16, wherein the third opening is shallower than the fourth opening.

18. The method for forming a semiconductor package as claimed in claim 16, wherein the second conductive layer is formed filling the third opening and the fifth opening, and the via is formed filling the fourth opening.

19. The method for forming a semiconductor package as claimed in claim 16, further comprising:
forming a second conductive trace filling the fifth opening of the second patterned insulating film.

20. The method for forming a semiconductor package as claimed in claim 13, wherein a first area of the conductive post is greater than a second area of the via in a plan view.
